(19) United States
(12) Patent Application Publication
(10) Pub. No.: US 2020/0343155 A1
(43) Pub. Date: Oct. 29, 2020

(54) POWER CONVERSION DEVICE

(71) Applicant: Mitsubishi Electric Corporation, Chiyoda ku, Tokyo (JP)

(72) Inventors: Hiroyuki KIYONAGA, Chiyoda-ku, Tokyo (JP); Kenta FUJII, Chiyoda-ku, Tokyo (JP); Tomohito FUKUDA, Chiyoda-ku, Tokyo (JP); Shuji WAKAIKI, Chiyoda-ku, Tokyo (JP); Takashi KUMAGAI, Chiyoda-ku, Tokyo (JP); Hiroshi IKARASHI, Chiyoda-ku, Tokyo (JP)

(73) Assignee: Mitsubishi Electric Corporation, Chiyoda-ku, Tokyo (JP)

(21) Appl. No.: 16/961,143

(22) PCT Filed: Jan. 9, 2019
(86) PCT No.: PCT/JP2019/000308

§ 371 Date: Jul. 9, 2020

(30) Foreign Application Priority Data
Jan. 25, 2018 (JP) 2018-010635

(51) Int. Cl. H01L 23/36; H01L 25/07; H01L 25/18; H05K 7/20; H01L 23/42; H05K 1/02; H01L 23/00

(52) U.S. Cl. CPC H01L 23/36; H01L 25/07; H01L 25/18; H05K 7/20436; H01L 2224/48247; H05K 1/0206; H01L 24/48; H01L 2224/48091; H01L 23/42

(57) ABSTRACT

A power conversion device that provides high heat dissipation and is easy to assemble. A power conversion device includes: a first heat dissipator; a second heat dissipator; a printed board having a first circuit pattern formed thereon; a first insulating member provided between first heat dissipator and printed board; a switching element including an electrode portion electrically bonded to first circuit pattern with a first bonding member interposed therebetween; a first fixing member bonded to an exposed surface of electrode portion; a heat dissipating member having one end bonded to first fixing member, and the other end provided between the switching element and second heat dissipator; a second insulating member sandwiched between second heat dissipator and switching element; and an installation portion.

### TECHNICAL FIELD

The present invention relates to a power conversion device and a method of manufacturing the power conversion device, and more specifically to a power conversion device having high heat dissipation and a method of manufacturing the power conversion device.

### BACKGROUND ART

A power conversion device generally includes a switching element that generates heat due to operation of the power conversion device. In recent years, in response to an increasing demand for miniaturization and higher output of power conversion devices, there has been an increase in the amount of heat generated per unit volume of the power conversion device. Since the switching element increases in temperature by generating heat due to the operation of the power conversion device, it is necessary not to exceed the allowable temperature of surrounding electronic components by the temperature of the switching element. There is a strong demand for improved heat dissipation of a power conversion device in order to achieve miniaturization and higher output of the power conversion device.

PTL 1 describes, as a cooling structure for improving heat dissipation of a power conversion device, a structure in which a thermal diffusion plate made of a highly thermally conductive material such as metal is disposed on an electrode portion of a switching element surface-mounted on a printed board, and this thermal diffusion plate is brought into contact with a cooling body with a thermally conductive rubber interposed therebetween.

PTL 2 describes a structure of a power conversion device in which an elastic and viscous heat dissipating member made of silicone rubber is disposed between an electrode portion of a switching element mounted on a printed board and a cooling body such that the heat dissipating member is crushed. The use of the elastic and viscous heat dissipating member made of silicone rubber as a heat dissipating member can allow the heat dissipating member to deform and enter minute projections and depressions on a surface of the electrode portion, to reduce thermal contact resistance between the electrode portion and the heat dissipating member. In addition, since the heat dissipating member is viscous, the possibility of the heat dissipating member being detached from the electrode of the switching element can be reduced during assembly of the printed board having the switching element mounted thereon, the heat dissipating member, and the cooling body.

### CITATION LIST

### Patent Literature

PTL 1: Japanese Patent Laying-Open No. 2005-135937

PTL 2: Japanese Patent Laying-Open No. 10-308484

### SUMMARY OF INVENTION

### Technical Problem

In the cooling structure of the power conversion device described in PTL 1, however, since the thermal diffusion plate made of a highly thermally conductive material such as metal is disposed in contact with the electrode portion of the switching element, minute gaps are formed at a contact surface between the electrode portion and the thermal diffusion plate due to the roughness of a surface of the electrode portion and a surface of the thermal diffusion plate. Air, which has an extremely low thermal conductivity, enters these minute gaps, resulting in an increase in thermal contact resistance between the electrode portion and the thermal diffusion plate and a reduction in heat dissipation.

In addition, during manufacture of the cooling structure described in PTL 1, since the thermal diffusion plate is not fixed to the electrode portion of the switching element, there is a possibility of the thermal diffusion plate being detached from the electrode of the switching element during assembly of the printed board having the switching element surface-mounted thereon, the thermal diffusion plate, the thermally conductive rubber, and the cooling body. The detachment of the thermal diffusion plate from the electrode of the switching element results in failure to dissipate the heat generated at the switching element through the thermal diffusion plate and the thermally conductive rubber to the cooling body, causing an increase in temperature of the switching element.

Although PTL 2 describes a heat dissipation structure of a power conversion device using silicone rubber as a heat dissipating member, silicone rubber has a thermal conductivity of only about one-hundredth or less than the thermal conductivity of metal. High heat dissipation cannot be obtained by disposing only the heat dissipating member made of silicone rubber as a heat dissipation path between the electrode portion of the switching element and the cooling body.

The present invention has been made to solve the problems as described above. A main object of the present invention is to provide a power conversion device that provides high heat dissipation and is easy to assemble, and a method of manufacturing the power conversion device.

### Solution to Problem

A power conversion device according to the present invention includes: a first heat dissipator; a second heat dissipator opposed to the first heat dissipator; a printed board having a front surface on which a first circuit pattern is formed, and a rear surface opposed to the first heat dissipator; a first insulating member provided between the first heat dissipator and the printed board; a switching element including an electrode portion having a rear surface electrically bonded to the first circuit pattern with a first bonding member interposed therebetween, the electrode portion being formed of a metal plate, a semiconductor chip electrically bonded to the electrode portion, and a resin portion sealing a part of a side of a front surface of the electrode portion and the semiconductor chip; a first fixing member having a rear surface bonded to an exposed surface on the side of the front surface of the electrode portion; a heat dissipating member having one end bonded to the front surface of the electrode portion with the first fixing member interposed therebetween, and the other end provided between a surface of the resin portion of the switching element opposed to the second heat dissipator and the second heat dissipator; a second insulating member sandwiched between the second heat dissipator and the heat dissipating member; and an installation portion that has one end coupled to the first heat dissipator and the other end coupled to the second heat dissipator, and that fixes the first heat dissipator and the second heat dissipator together.

A method of manufacturing a power conversion device according to the present invention includes: a bonding member forming step of forming a first bonding member and a second bonding member on a first circuit pattern formed on a front surface of a printed board; a disposing step of disposing a switching element, which includes an electrode portion formed of a metal plate, a semiconductor chip electrically bonded to the electrode portion, a lead terminal having one end electrically bonded to the semiconductor chip by a wire, and a resin portion sealing a part of a side of a front surface of the electrode portion, the other end of the lead terminal and the semiconductor chip, such that the electrode portion is positioned on the first bonding member and the lead terminal is positioned on the second bonding member, disposing a first fixing member on an exposed surface on the side of the front surface of the electrode portion of the switching element, and disposing a heat dissipating member such that the heat dissipating member has one end positioned on a front surface of the first fixing member and the other end positioned on a front surface of the resin portion of the switching element; a bonding step of simultaneously performing electrical bonding of the electrode portion to the first circuit pattern, electrical bonding of the lead terminal to the first circuit pattern, and bonding of the one end of the heat dissipating member to the electrode portion, by soldering in a reflow process of heating at a temperature higher than melting points of both the first bonding member and the second bonding member; and a fixing step of disposing a first insulating member on a front surface of a first heat dissipator, disposing the printed board on a front surface of the first insulating member, disposing a second insulating member on a front surface of the other end of the heat dissipating member, and disposing a second heat dissipator on the second insulating member, and fixing the first heat dissipator to the second heat dissipator by an installation portion.

### Advantageous Effects of Invention

According to the power conversion device according to the present invention, heat generated at the semiconductor chip can be dissipated to the heat dissipators through a plurality of heat dissipation paths, so that high heat dissipation can be obtained.

According to the method of manufacturing a power conversion device according to the present invention, electrical bonding of the electrode portion to the first circuit pattern, electrical bonding of the lead terminal to the first circuit pattern, and bonding of the first fixing portion to the electrode portion are simultaneously performed by soldering in a reflow process of heating at a temperature higher than melting points of all of the first bonding member, the second bonding member and the first fixing member, so that the assembly of the power conversion device can be simplified.

### BRIEF DESCRIPTION OF DRAWINGS

FIG. 1 is a perspective view of a power conversion device according to a first embodiment of the present invention.

FIG. 2 is a perspective view of the power conversion device according to the first embodiment of the present invention.

FIG. 3 is a perspective view of the power conversion device according to the first embodiment of the present invention.

FIG. 4 is a cross-sectional view of the power conversion device according to the first embodiment of the present invention.

FIG. 5 is a perspective view of a switching element and a heat dissipating member of the power conversion device according to the first embodiment of the present invention.

FIG. 6 is a perspective view of the switching element and the heat dissipating member of the power conversion device according to the first embodiment of the present invention.

FIG. 7 is a perspective view of the switching element and the heat dissipating member of a power conversion device according to a second embodiment of the present invention.

FIG. 8 is a cross-sectional view of a power conversion device according to a third embodiment of the present invention.

FIG. 9 is a cross-sectional view of a power conversion device according to a fourth embodiment of the present invention.

FIG. 10 is a perspective view of the switching element and the heat dissipating member of the power conversion device according to the fourth embodiment of the present invention.

FIG. 11 is a cross-sectional view of a power conversion device according to a fifth embodiment of the present invention.

FIG. 12 is a perspective view of the switching element and the heat dissipating member of the power conversion device according to the fifth embodiment of the present invention.

FIG. 13 is a perspective view of the switching element and the heat dissipating member of the power conversion device according to the fifth embodiment of the present invention.

FIG. 14 is a cross-sectional view of a power conversion device according to a sixth embodiment of the present invention.

FIG. 15 is a cross-sectional view of the power conversion device according to the sixth embodiment of the present invention.

FIG. 16 is a cross-sectional view of a power conversion device according to a seventh embodiment of the present invention.

FIG. 17 is a cross-sectional view of the power conversion device according to the seventh embodiment of the present invention.

FIG. 18 is a cross-sectional view of the power conversion device according to the seventh embodiment of the present invention.

FIG. 19 is a cross-sectional view of the power conversion device according to the seventh embodiment of the present invention.

### DESCRIPTION OF EMBODIMENTS

### First Embodiment

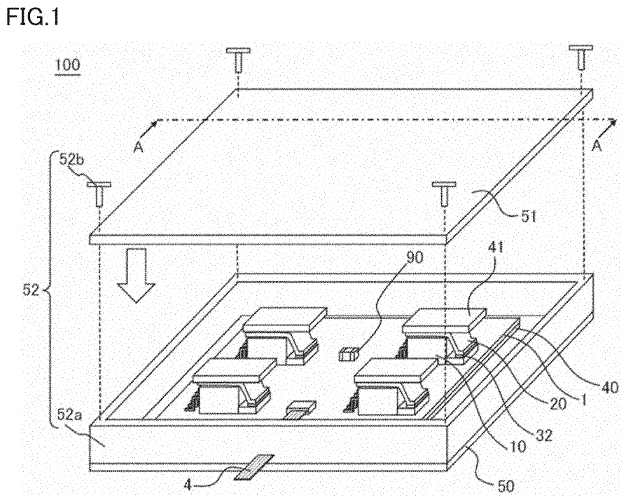

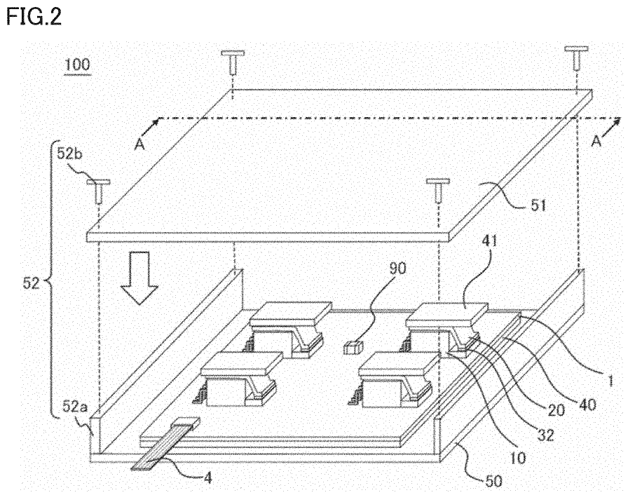

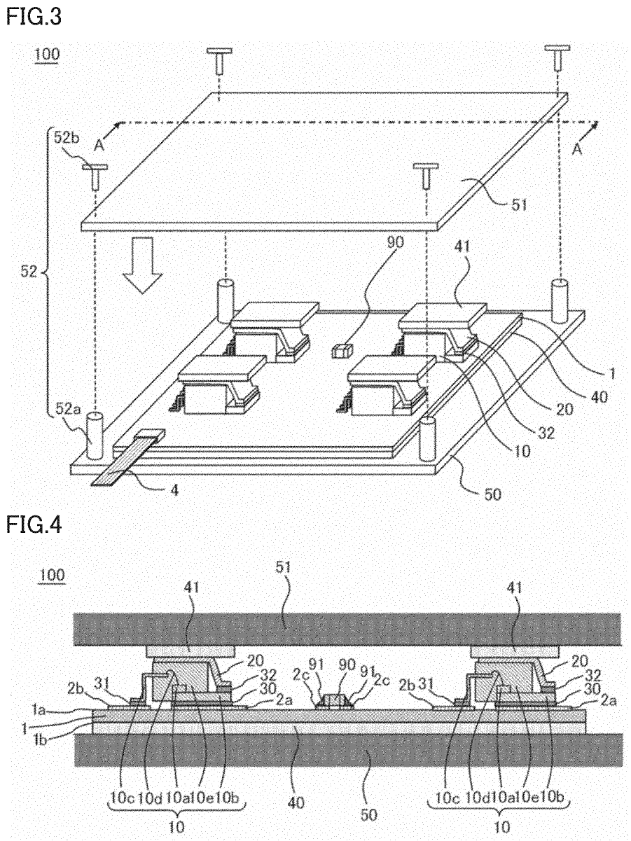

FIG. 1 is a perspective view of a power conversion device 100 according to a first embodiment. FIGS. 2 and 3 are perspective views showing variations of power conversion device 100 according to the first embodiment. FIG. 4 is a cross-sectional view taken along A-A in FIG. 1. As shown in FIG. 1, power conversion device 100 includes a first heat dissipator 50, a printed board 1 opposed to first heat dissipator 50, a first insulating member 40 provided between first heat dissipator 50 and printed board 1, a switching element 10 electrically bonded on printed board 1, a heat dissipating member 20 bonded to a part of switching element 10 by a first fixing member 32, a second heat dissipator 51 opposed to first heat dissipator 50, a second insulating member 41 sandwiched between heat dissipating member 20 and second heat dissipator 51, and an installation portion 52 to fix first heat dissipator 50 and second heat dissipator 51 together.

Power conversion device 100 is connected to an external power supply through a harness 4 shown in FIGS. 1 to 3. Harness 4 is electrically connected to either a first circuit pattern 2a or a first circuit pattern 2b, and harness 4 is utilized to supply electric power from the external power supply to switching element 10 of power conversion device 100.

Printed board 1 includes a first main surface 1a and a second main surface 1b. Printed board 1 is fixed to first heat dissipator 50 with first insulating member 40 interposed therebetween. Printed board 1 is made of a material having a low thermal conductivity, such as glass-reinforced epoxy, phenolic resin, polyphenylene sulfide (PPS), or polyether ether ketone (PEEK). Printed board 1 may be made of, as the material having a low thermal conductivity, ceramics such as aluminum oxide, aluminum nitride, or silicon carbide.

As shown in FIG. 4, first circuit patterns 2a and 2b are formed on first main surface 1a of printed board 1. First circuit patterns 2a and 2b have a thickness of not less than 1 μm and not more than 2000 First circuit patterns 2a and 2b are made of an electrically conductive material, such as nickel, gold, aluminum, silver, tin, or an alloy thereof. First circuit patterns 2a and 2b are not limited to be formed on first main surface 1a of printed board 1, and may be provided on second main surface 1b, within printed board 1, and the like.

Switching element 10 is electrically bonded on first main surface 1a of printed board 1. The number of switching elements 10 and their disposition on first main surface 1a of printed board 1 are appropriately selected depending on the power conversion device applied.

Switching element 10 is a power semiconductor element such as a transistor, a metal oxide semiconductor field effect transistor (MOSFET), an insulated gate bipolar transistor (IGBT), or a diode.

FIG. 5 is a perspective view of switching element 10 and heat dissipating member 20 of power conversion device 100 according to the first embodiment. As shown in FIGS. 4 and 5, switching element 10 includes a semiconductor chip 10a, an electrode portion 10b, a wire 10d, a lead terminal 10c, and a resin portion 10e. Semiconductor chip 10a is electrically bonded to electrode portion 10b. Electrode portion 10b is a metal plate, for example. Electrode portion 10b protrudes from a side surface of resin portion 10e. Semiconductor chip 10a is electrically connected to lead terminal 10c by wire 10d. Lead terminal 10c protrudes from a side surface of resin portion 10e opposite to the side surface from which electrode portion 10b protrudes. Resin portion 10e seals semiconductor chip 10a, and a part of each of electrode portion 10b, wire 10d and lead terminal 10c therein. A surface of switching element 10 which is electrically bonded to the first circuit pattern with electrode portion 10b is referred to as a heat dissipation surface 10f, and a surface of switching element 10 which is sealed by resin portion 10e on the side opposite to heat dissipation surface 10f is referred to as a sealed surface 10g. A surface of electrode portion 10b protruding from the side surface of resin portion 10e on the side opposite to heat dissipation surface 10f is referred to as an exposed surface.

Semiconductor chip 10a is made of, for example, silicon, silicon carbide, gallium nitride, or gallium arsenide.

Electrode portion 10b and first circuit pattern 2a are electrically bonded together by a first bonding member 30, and lead terminal 10c and first circuit pattern 2b are electrically bonded together by a second bonding member 31.

When there are a plurality of switching elements 10 disposed on first main surface 1a of printed board 1, an electronic component 90 may be surface-mounted on a first circuit pattern 2c between disposed switching elements 10, with a third bonding member 91 interposed therebetween. Electronic component 90 is, for example, a surface-mounted chip resistor, a chip capacitor, or an integrated circuit (IC) component. When electronic component 90 is a through hole component, a through hole and a circuit pattern for mounting the through hole component are formed between disposed switching elements 10. The number and disposition of electronic components 90 are appropriately selected depending on the power conversion device applied.

First bonding member 30, second bonding member 31 and third bonding member 91 are electrically conductive, and are made of a bonding material such as solder or an electrically conductive adhesive.

Heat dissipating member 20 includes a first fixing portion 20a bonded to electrode portion 10b of switching element 10 by first fixing member 32, and a heat dissipating portion 20b mechanically fixed on sealed surface 10g of switching element 10.

Heat dissipating portion 20b should only be provided between sealed surface 10g of resin portion 10e of switching element 10 opposed to second heat dissipator 51 and second heat dissipator 51, and does not need to be mechanically fixed on sealed surface 10g of switching element 10. A surface of heat dissipating portion 20b opposed to second heat dissipator 51 preferably has an area equal to or greater than that of sealed surface 10g of switching element 10.

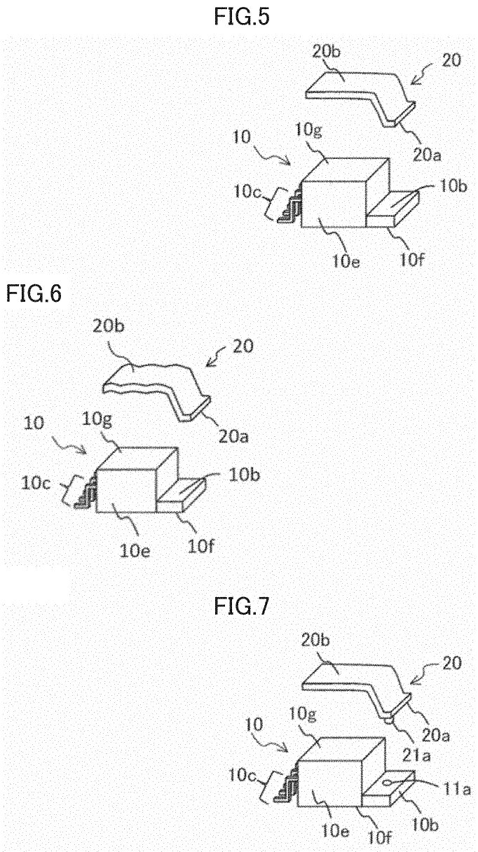

FIG. 6 is a perspective view showing a variation of switching element 10 and heat dissipating member 20 of power conversion device 100 according to the first embodiment. Heat dissipating portion 20b shown in FIG. 6 is formed in a wave pattern.

Heat dissipating member 20 has a high thermal conductivity, and is made of a highly thermally conductive material such as copper, a copper alloy, nickel, a nickel alloy, iron, an iron alloy, gold, or silver. Heat dissipating member 20 may employ, for example, a highly thermally conductive material in which a surface of one of aluminum, an aluminum alloy, a magnesium alloy and the like is plated with one of a nickel plating film, a gold plating film, a tin plating film, and a copper plating film. Heat dissipating member 20 may employ, for example, a highly thermally conductive material in which a surface of a ceramic material such as aluminum oxide or aluminum nitride is plated with one of a nickel plating film, a gold plating film, a tin plating film, and a copper plating film. Heat dissipating member 20 may employ, for example, a highly thermally conductive material in which a surface of resin having a high thermal conductivity is plated with one of a nickel plating film, a gold plating film, a tin plating film, and a copper plating film.

Heat dissipating member 20 has a thickness of from 0.1 mm to 3 mm, and is formed of a member in the form of a plate having a high thermal conductivity. Heat dissipating member 20 has a thermal conductivity of not less than 1.0 W/(m·K), preferably not less than 10.0 W/(m·K), and more preferably not less than 100.0 W/(m·K).

First fixing member 32 is made of a material having a high thermal conductivity, such as a thermally conductive adhesive, an electrically conductive adhesive, or solder.

First insulating member 40 is sandwiched between first heat dissipator 50 and second main surface 1b of printed board 1. When first insulating member 40 is made of a viscous material, first insulating member 40 is bonded to each member.

Second insulating member 41 is sandwiched between second heat dissipator 51 and heat dissipating portion 20b of heat dissipating member 20. When second insulating member 41 is made of a viscous material, second insulating member 41 is bonded to each member.

First insulating member 40 and second insulating member 41 are electrically insulative, and have a thermal conductivity of not less than 0.1 W/(m·K), and preferably not less than 1.0 W/(m·K). Further, first insulating member 40 and second insulating member 41 preferably have a good elasticity, that is, a Young's modulus of not less than 1 MPa and not more than 100 MPa.

First insulating member 40 and second insulating member 41 are made of a satisfactory insulating material, for example, a rubber material such as silicon or urethane, or a resin material such as acrylonitrile butadiene styrene (ABS), polybutylene terephthalate (PBT), polyphenylene sulfide (PPS), or phenol. A polymeric material such as polyimide may be used, for example, as the material for first insulating member 40 and second insulating member 41. A ceramic material having particles of one of aluminum oxide, aluminum nitride, boron nitride and the like mixed therein, or a silicon resin having particles of one of aluminum oxide, aluminum nitride, boron nitride and the like mixed therein may be used, for example, as the material for first insulating member 40 and second insulating member 41.

First heat dissipator 50 and second heat dissipator 51 are opposed to each other. The surface of first heat dissipator 50 opposed to second heat dissipator 51 is referred to as a front surface of first heat dissipator 50, and the surface of second heat dissipator 51 opposed to first heat dissipator 50 is referred to as a rear surface of second heat dissipator 51. On the front surface of first heat dissipator 50, printed board 1 is provided with first insulating member 40 interposed therebetween, and the rear surface of second heat dissipator 51 is fixed on heat dissipating portion 20b with second insulating member 41 interposed therebetween. First heat dissipator 50 and second heat dissipator 51 are fixed together by installation portion 52 coupled to first heat dissipator 50 and second heat dissipator 51.

It may be that first insulating member 40 is sandwiched between the front surface of first heat dissipator 50 and printed board 1, second insulating member 41 is sandwiched between the rear surface of second heat dissipator 51 and heat dissipating portion 20b, and first heat dissipator 50 and second heat dissipator 51 are fixed together by installation portion 52 coupled to first heat dissipator 50 and second heat dissipator 51.

Installation portion 52 includes a spacer 52a and a fastening member 52b. Switching element 10 is pressed by first heat dissipator 50 and second heat dissipator 51 by fastening with installation portion 52. Specifically, switching element 10 is pressed by first heat dissipator 50 and second heat dissipator 51 by fastening with fastening member 52b.

Spacer(s) 52a may be configured such that it is provided to surround the plurality of switching elements 10 as shown in FIG. 1, or such that they are provided on opposite sides of first heat dissipator 50 as shown in FIG. 2, or such that they are provided near the vertices of first heat dissipator 50 as shown in FIG. 3. That is, the configuration is appropriately selected depending on the specifications of a power conversion device applied. While spacer 52a is provided on first heat dissipator 50 in the configurations shown in FIGS. 1 to 3, spacer 52a may be provided on second heat dissipator 51.

Because of the pressing in a direction of switching element 10 by first heat dissipator 50 and second heat dissipator 51, printed board 1, switching element 10, heat dissipating member 20, first bonding member 30, second bonding member 31, first fixing member 32, first insulating member 40 and second insulating member 41 provided in first heat dissipator 50 are pressed, to constitute power conversion device 100. The fixation of first heat dissipator 50 to second heat dissipator 51 by installation portion 52 is not limited to the manner described above. Spacer 52a may be welded to first heat dissipator 50 and second heat dissipator 51, or spacer 52a may be sandwiched between first heat dissipator 50 and second heat dissipator 51 using an elastic member (not shown).

First heat dissipator 50 and second heat dissipator 51 are formed of a cooling body having a thermal conductivity of not less than 1.0 W/(m·K), preferably not less than 10.0 W/(m·K), and more preferably not less than 100.0 W/(m·K). Examples of a material for first heat dissipator 50 and second heat dissipator 51 include a metal material such as copper, iron, aluminum, an iron alloy or an aluminum alloy, or resin having a high thermal conductivity.

A method of manufacturing power conversion device 100 according to the first embodiment is now described. The side of first heat dissipator 50 will be referred to as a lower portion, and the side of second heat dissipator 51 will be referred to as an upper portion in the description.

The method of manufacturing power conversion device 100 according to the first embodiment will be described with reference to a case where first bonding member 30, second bonding member 31 and third bonding member 91 are solder, and first fixing member 32 is solder having a melting point equal to or lower than those of first bonding member 30, second bonding member 31 and third bonding member 91 (hereinafter referred to as a condition 1), and a case where first bonding member 30, second bonding member 31 and third bonding member 91 are solder, and first fixing member 32 is a thermally conductive adhesive or an electrically conductive adhesive having heat resistance exceeding the melting points of first bonding member 30, second bonding member 31 and third bonding member 91 (hereinafter referred to as a condition 2).

(In the Case of Condition 1)

In a bonding member forming step, first bonding member 30, second bonding member 31 and third bonding member 91 are applied, using a printer, to first main surface 1a of printed board 1 having first circuit patterns 2a, 2b and 2c formed thereon.

In a disposing step, switching element 10, which includes electrode portion 10b, semiconductor chip 10a electrically bonded on electrode portion 10b, lead terminal 10c having one end electrically bonded to semiconductor chip 10a by wire 10d, and resin portion 10e sealing a part of a side of a front surface of electrode portion 10b, the other end of lead terminal 10c and semiconductor chip 10a, is disposed, using an electronic component mounting machine, such that electrode portion 10b is positioned on first bonding member 30 and lead terminal 10c is positioned on second bonding member 31. In addition, electronic component 90 is disposed on third bonding member 91 using the electronic component mounting machine, first fixing member 32 is disposed on the exposed surface on the side of the front surface of electrode portion 10b of switching element 10 using the electronic component mounting machine, and heat dissipating member 20 is disposed, using the electronic component mounting machine, such that first fixing portion 20a of heat dissipating member 20 is positioned on a front surface of first fixing member 32 and heat dissipating portion 20b of heat dissipating member 20 is positioned on sealed surface 10g of switching element 10.

In a bonding step, electrical bonding of electrode portion 10b to first circuit pattern 2a, electrical bonding of lead terminal 10c to first circuit pattern 2b, electrical bonding of electronic component 90 to first circuit pattern 2c, and bonding of first fixing portion 20a to electrode portion 10b are simultaneously performed by soldering in a reflow process of heating at a temperature higher than the melting points of all of first bonding member 30, second bonding member 31 and third bonding member 91.

In a fixing step, first insulating member 40 is disposed on the front surface of first heat dissipator 50, printed board 1 is disposed such that the second main surface of printed board 1 is positioned on a front surface of first insulating member 40, second insulating member 41 is disposed on heat dissipating portion 20b of heat dissipating member 20, and second heat dissipator 51 is disposed on second insulating member 41, and first heat dissipator 50 and second heat dissipator 51 are fixed together by installation portion 52.

(In the Case of Condition 2)

In a disposing step, first fixing member 32 is disposed, using an electronic component mounting machine, on the exposed surface on the side of the front surface of electrode portion 10b of switching element 10, which includes electrode portion 10b, semiconductor chip 10a electrically bonded on electrode portion 10b, lead terminal 10c having one end electrically bonded to semiconductor chip 10a by wire 10d, and resin portion 10e sealing a part of the side of the front surface of electrode portion 10b, the other end of lead terminal 10c and semiconductor chip 10a, and heat dissipating member 20 is disposed, using the electronic component mounting machine, such that first fixing portion 20a of heat dissipating member 20 is positioned on sealed surface 10g of switching element 10, and heat dissipating portion 20b of heat dissipating member 20 is positioned on first fixing member 32.

In a heat dissipating member bonding step, first fixing portion 20a of heat dissipating member 20 is bonded to electrode portion 10b of switching element 10 by first fixing member 32.

In a bonding member forming step, first bonding member 30, second bonding member 31 and third bonding member 91 are applied, using a printer, to first main surface 1a of printed board 1 having first circuit patterns 2a, 2b and 2c formed thereon.

In a bonding step, switching element 10 is disposed, using the electronic component mounting machine, such that electrode portion 10b is positioned on first bonding member 30 and lead terminal 10c is positioned on second bonding member 31. In addition, electronic component 90 is disposed on third bonding member 91 using the electronic component mounting machine, and electrical bonding of electrode portion 10b to first circuit pattern 2a, electrical bonding of lead terminal 10c to first circuit pattern 2b, and electrical bonding of electronic component 90 to first circuit pattern 2c are simultaneously performed by soldering in a reflow process of heating at a temperature lower than the melting point of first fixing member 32.

In a fixing step, first insulating member 40 is disposed on the front surface of first heat dissipator 50, printed board 1 is disposed such that the second main surface of printed board 1 is positioned on the front surface of first insulating member 40, second insulating member 41 is disposed on heat dissipating portion 20b of heat dissipating member 20, and second heat dissipator 51 is disposed on second insulating member 41, and first heat dissipator 50 and second heat dissipator 51 are fixed together by installation portion 52.

In the method of manufacturing power conversion device 100 according to the first embodiment, in the case of condition 1, electrical bonding of electrode portion 10b to first circuit pattern 2a, electrical bonding of lead terminal 10c to first circuit pattern 2b, electrical bonding of electronic component 90 to first circuit pattern 2c, and bonding of first fixing portion 20a to electrode portion 10b are simultaneously performed by soldering in a reflow process of heating at a temperature higher than the melting points of all of first bonding member 30, second bonding member 31 and third bonding member 91. Thus, it is not required to provide a new manufacturing step for bonding heat dissipating member 20 to electrode portion 10b of switching element 10, so that the assembly of power conversion device 100 according to the first embodiment can be simplified.

In the case of condition 2, electrical bonding of electrode portion 10b to first circuit pattern 2a, electrical bonding of lead terminal 10c to first circuit pattern 2b, and bonding of electronic component 90 to first circuit pattern 2c are simultaneously performed by soldering in a reflow process of heating at a temperature lower than the melting point of first fixing member 32. Thus, components can be supplied in manufacturing steps with switching element 10 being bonded to heat dissipating member 20, so that the assembly of power conversion device 100 according to the first embodiment can be simplified.

In addition, heat dissipating member 20 is bonded with first fixing member 32 to the portion not covered with resin portion 10e on the side of sealed surface 10g of electrode portion 10b of switching element 10. Thus, care does need to be taken to prevent the detachment of heat dissipating member 20 from electrode portion 10b of the switching element during the assembly of power conversion device 100, so that the assembly of power conversion device 100 according to the first embodiment can be simplified.

When power conversion device 100 according to the first embodiment is manufactured with a conventional manufacturing method, during the fixation of first heat dissipator 50 to second heat dissipator 51 by installation portion 52, gaps may be formed between heat dissipating portion 20b of heat dissipating member 20 and second insulating member 41, and between second insulating member 41 and second heat dissipator 51, due to the processing accuracy of heat dissipating member 20, resulting in a reduction in heat dissipation of a heat dissipation path through which the heat generated at semiconductor chip 10a is dissipated through electrode portion 10b, first fixing member 32, heat dissipating member 20 and second insulating member 41 to second heat dissipator 51.

In contrast, in the method of manufacturing power conversion device 100 according to the first embodiment, in the case of condition 2, since a thermally conductive adhesive or an electrically conductive adhesive that is cured over a certain period of time is used as first fixing member 32, first heat dissipator 50 and second heat dissipator 51 can be fixed together by installation portion 52 before first fixing member 32 is cured. Thus, the occurrence of a problem can be suppressed, such as the formation of gaps between heat dissipating portion 20b of heat dissipating member 20 and second insulating member 41, and between second insulating member 41 and second heat dissipator 51, due to the deformation of first fixing member 32 by the pressing in the direction of switching element 10 by first heat dissipator 50 and second heat dissipator 51.

Accordingly, the thermal design does not need to take into account the reduction in heat dissipation of power conversion device 100 due to the processing accuracy of heat dissipating member 20.

Effects produced by power conversion device 100 according to the first embodiment will now be described.

The heat generated at semiconductor chip 10a as a conduction loss or a switching loss due to the operation of power conversion device 100 is dissipated through electrode portion 10b, first fixing member 32, heat dissipating member 20 and second insulating member 41 to second heat dissipator 51. In the power conversion device described in PTL 1, since first fixing member 32 is not used, minute gaps may be formed at a contact surface between electrode portion 10b and heat dissipating member 20 due to the surface roughness of electrode portion 10b and heat dissipating member 20, and air having an extremely low thermal conductivity may enter such gaps, resulting in an increase in thermal contact resistance between electrode portion 10b and heat dissipating member 20.

In contrast, in power conversion device 100 according to the first embodiment, minute gaps are not formed because of the bonding of electrode portion 10b to heat dissipating member 20 by first fixing member 32, and the use of first fixing member 32 having a higher thermal conductivity than the thermal conductivity of 0.02 W/(m·K) of air can significantly reduce the thermal contact resistance between electrode portion 10b and heat dissipating member 20.

Further, since second insulating member 41 has a good elasticity, second insulating member 41 is crushed between heat dissipating portion 20b and second heat dissipator 51, to prevent the formation of minute gaps between heat dissipating portion 20b and second insulating member 41, and between second insulating member 41 and second heat dissipator 51. Further, the use of the material having a higher thermal conductivity than the thermal conductivity of 0.02 W/(m·K) of air as second insulating member 41 can reduce thermal contact resistance between heat dissipating portion 20b and second insulating member 41, and thermal contact resistance between second insulating member 41 and second heat dissipator 51.

Further, since heat dissipating member 20 is made of a material having a high thermal conductivity, thermal resistance between electrode portion 10b and second insulating member 41 can be significantly reduced. As a result, power conversion device 100 can have improved heat dissipation. Therefore, the increase in temperature of switching element 10 due to the operation of power conversion device 100 can be suppressed. As a result, power conversion device 100 according to the first embodiment is capable of operation with high output.

Further, in addition to a first heat dissipation path through which the heat is dissipated through electrode portion 10b, first fixing member 32, heat dissipating member 20 and second insulating member 41 to second heat dissipator 51, power conversion device 100 includes a second heat dissipation path through which the heat is dissipated from sealed surface 10g through heat dissipating portion 20b and second insulating member 41 to second heat dissipator 51, and a third heat dissipation path through which the heat is dissipated through electrode portion 10b, first bonding member 30, first circuit pattern 2a, printed board 1 and first insulating member 40 to first heat dissipator 50, as heat dissipation paths through which to dissipate the heat generated at semiconductor chip 10a. The provision of the plurality of heat dissipation paths can improve the heat dissipation of power conversion device 100 for the heat generated at semiconductor chip 10a, and suppress the increase in temperature of switching element 10 due to the operation of power conversion device 100. As a result, power conversion device 100 according to the first embodiment is capable of operation with high output.

When heat dissipating portion 20b of heat dissipating member 20 has a wave-like structure as shown in FIG. 6, the area of contact between heat dissipating portion 20b and second insulating member 41 can be increased. With the wave-like structure as the shape of heat dissipating portion 20b, power conversion device 100 can further reduce the thermal contact resistance between heat dissipating portion 20b and second insulating member 41, thereby improving the heat dissipation of the first heat dissipation path.

During the soldering of switching element 10 and electronic component 90 to printed board 1 in a reflow process, printed board 1 may be warped due to the difference in coefficient of linear expansion between printed board 1 and switching element 10, and between printed board 1 and electronic component 90. If gaps are formed between printed board 1 and first insulating member 40 or between first insulating member 40 and the front surface of first heat dissipator 50 due to the warpage of printed board 1, the heat dissipation is reduced in the third heat dissipation path through which the heat generated at semiconductor chip 10a is dissipated through electrode portion 10b, first bonding member 30, first circuit pattern 2a, printed board 1 and first insulating member 40 to first heat dissipator 50.

In power conversion device 100 according to the first embodiment, on the front surface of first heat dissipator 50, printed board 1 including switching element 10 is provided via first insulating member 40, and second heat dissipator 51 is provided via second insulating member 41 provided on heat dissipating portion 20b of heat dissipating member 20. First heat dissipator 50 and second heat dissipator 51 are fixed together by installation portion 52. Here, first heat dissipator 50 and second heat dissipator 51 are fixed together by installation portion 52 such that, at the location where switching element 10 is disposed on printed board 1, printed board 1 is pressed between second heat dissipator 51 and first heat dissipator 50 through first insulating member 40, heat dissipating member 20, switching element 10 and second insulating member 41. As a result, the warpage of printed board 1 is suppressed so as to eliminate the gaps between printed board 1 and first insulating member 40 and between first insulating member 40 and the front surface of first heat dissipator 50 caused by the warpage of printed board 1. Thus, at the location where switching element 10 is disposed on printed board 1, stable contact can be achieved between second main surface 1b of printed board 1 and first insulating member 40, and between first insulating member 40 and the front surface of first heat dissipator 50. Therefore, the thermal design does not need to take into account the reduction in heat dissipation of power conversion device 100 for the heat generated at semiconductor chip 10a, which is caused by the warpage of printed board 1.

When there are a plurality of switching elements 10 disposed on first main surface 1a of printed board 1, the warpage of printed board 1 can be suppressed at the location where each switching element 10 is disposed, so that the warpage of printed board 1 can be suppressed also at the location where electronic component 90 is disposed between switching elements 10. As a result, when mounting electronic component 90 between switching elements 10, the design does not need to take into account stress applied to electronic component 90 due to the warpage of printed board 1, and stress applied to third bonding member 91 that bonds electronic component 90 to first circuit pattern 2c.

Since electrode portion 10b and first fixing portion 20a are bonded together by first fixing member 32, the mechanical fixation of heat dissipating member 20 can be made more robust than the power conversion devices described in PTL 1 and PTL 2. As a result, power conversion device 100 can have improved vibration resistance.

When heat dissipating member 20, first heat dissipator 50 and second heat dissipator 51 are made of metal, heat dissipating member 20, first heat dissipator 50 and second heat dissipator 51 can serve as electromagnetic shields, thereby shielding electromagnetic wave noise emitted from electronic devices and the like disposed around power conversion device 100, and the emission of electromagnetic wave noise generated from semiconductor chip 10a to the outside of power conversion device 100. Thus, malfunction of power conversion device 100 and other electronic devices disposed around power conversion device 100 can be suppressed.

### Second Embodiment

The configuration of a power conversion device 200 according to a second embodiment of the present invention is described. Description of the configuration identical to or corresponding to that of the first embodiment is not repeated, and only a different portion of the configuration is described.

FIG. 7 is a perspective view of switching element 10 and heat dissipating member 20 of power conversion device 200 according to the second embodiment. In power conversion device 200 according to the second embodiment, electrode portion 10b of switching element 10 is provided with a through hole 11a, and heat dissipating portion 20b of heat dissipating member 20 is provided with a protrusion 21a.

Protrusion 21a is formed by a drawing process of a metal plate, for example. The formation of protrusion 21a is not limited to the above. For example, formation by casting, injection molding of a ceramic material, formation by cast molding, or formation by cutting a metal or ceramics may be used.

In power conversion device 200 according to the second embodiment, protrusion 21a can be fitted in through hole 11a in electrode portion 10b, to prevent displacement of heat dissipating member 20 from a prescribed position during the disposition of heat dissipating member 20 on electrode portion 10b of switching element 10 with first fixing member 32 interposed therebetween.

### Third Embodiment

The configuration of a power conversion device 300 according to a third embodiment of the present invention is described. Description of the configuration identical to or corresponding to those of the first and second embodiments is not repeated, and only a different portion of the configuration is described.

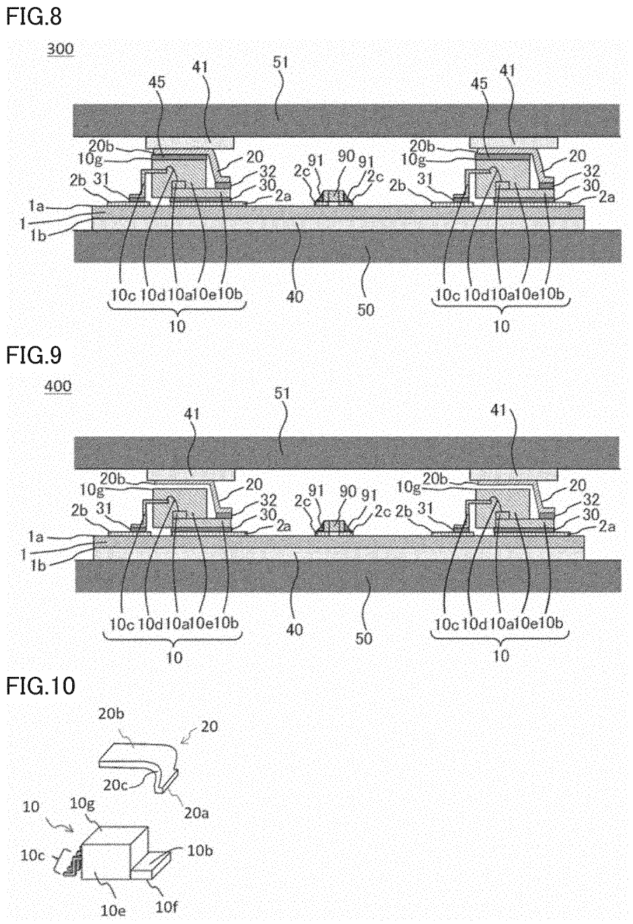

FIG. 8 is a cross-sectional view of power conversion device 300 according to the third embodiment. Power conversion device 300 according to the third embodiment includes a thermally conductive member 45 between sealed surface 10g of switching element 10 and heat dissipating portion 20b of heat dissipating member 20.

Thermally conductive member 45 is sandwiched between sealed surface 10g of switching element 10 and heat dissipating portion 20b of heat dissipating member 20. When thermally conductive member 45 is made of a viscous material, first insulating member 40 is bonded to each member.

Thermally conductive member 45 has a thermal conductivity of not less than 0.1 W/(m·K), preferably not less than 1.0 W/(m·K), and more preferably not less than 10.0 W/(m·K). Examples of thermally conductive member 45 include a thermally conductive grease, a thermally conductive sheet, and a thermally conductive adhesive.

In power conversion device 300 according to the third embodiment, sealed surface 10g of switching element 10 is brought into contact with heat dissipating portion 20b of heat dissipating member 20 with thermally conductive member 45 interposed therebetween. Thus, the formation of minute gaps due to the surface roughness of sealed surface 10g and heat dissipating member 20 can be suppressed, thereby improving the heat dissipation of the second heat dissipation path through which the heat generated at semiconductor chip 10a is dissipated from sealed surface 10g through heat dissipating portion 20b and second insulating member 41 to second heat dissipator 51.

### Fourth Embodiment

The configuration of a power conversion device 400 according to a fourth embodiment of the present invention is described. Description of the configuration identical to or corresponding to those of the first, second and third embodiments is not repeated, and only a different portion of the configuration is described.

FIG. 9 is a cross-sectional view of power conversion device 400 according to the fourth embodiment. In power conversion device 400 according to the fourth embodiment, a gap is provided between sealed surface 10g of switching element 10 and heat dissipating portion 20b of heat dissipating member 20.

Because of the provision of the gap between sealed surface 10g and heat dissipating portion 20b, the heat dissipation through the second heat dissipation path is eliminated, resulting in a reduction in heat dissipating effect. However, since the second heat dissipation path dissipates a smaller amount of heat than the first heat dissipation path or the third heat dissipation path, the improvement in heat dissipation of the power conversion device is not hindered.

In power conversion device 400 according to the fourth embodiment, because of the provision of the gap between heat dissipating portion 20b and sealed surface 10g, during the fixation of first heat dissipator 50 to second heat dissipator 51 by installation portion 52, stress applied to resin portion 10e of switching element 10 from heat dissipating portion 20b of heat dissipating member 20 through second insulating member 41 can be relaxed. Therefore, the design does not need to take into account the stress applied to resin portion 10e of switching element 10.

FIG. 10 is a perspective view showing a variation of switching element 10 and heat dissipating member 20 of power conversion device 400 according to the fourth embodiment. Heat dissipating member 20 shown in FIG. 10 includes a spring portion 20c.

When heat dissipating member 20 includes spring portion 20c, during the fixation of first heat dissipator 50 to second heat dissipator 51 by installation portion 52, stress applied to a bonded surface between first fixing portion 20a and first fixing member 32 due to the pressing of heat dissipating member 20 by second heat dissipator 51 through second insulating member 41 can be relaxed. Therefore, the design does not need to take into account the stress applied to the bonded surface between first fixing portion 20a and first fixing member 32.

### Fifth Embodiment

The configuration of a power conversion device 500 according to a fifth embodiment of the present invention is described. Description of the configuration identical to or corresponding to those of the first, second, third and fourth embodiments is not repeated, and only a different portion of the configuration is described.

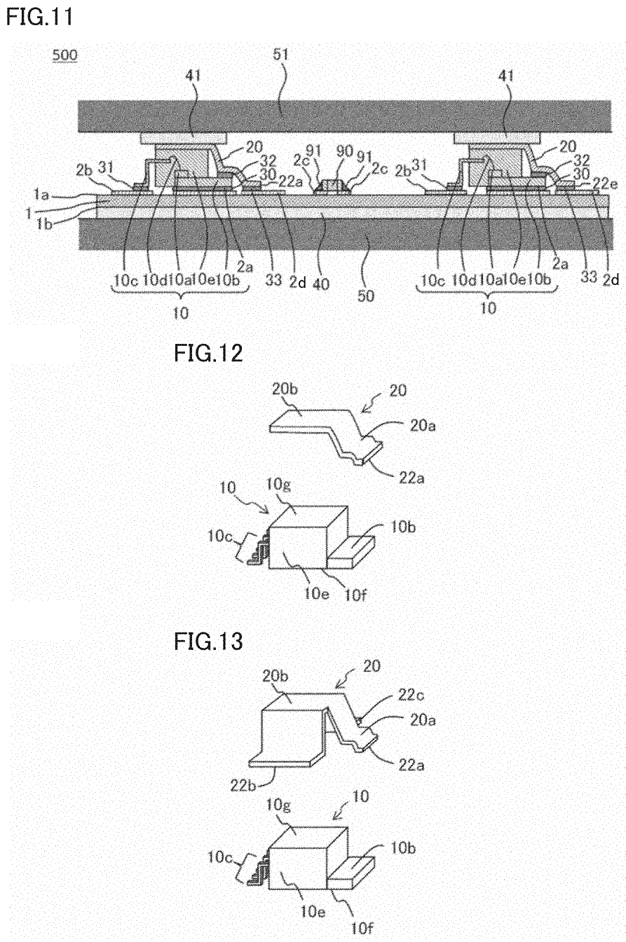

FIG. 11 is a cross-sectional view of power conversion device 500 according to the fifth embodiment. FIG. 12 is a perspective view of switching element 10 and heat dissipating member 20 of power conversion device 500 according to the fifth embodiment. FIG. 13 is a perspective view showing a variation of switching element 10 and heat dissipating member 20 of power conversion device 500 according to the fifth embodiment. In power conversion device 500 according to the fifth embodiment, a fixing member bonded on the first circuit pattern is referred to as a second fixing member 33.

Heat dissipating member 20 of power conversion device 500 according to the fifth embodiment further includes a second fixing portion 22a bonded to first circuit pattern 2d formed on first main surface 1a of printed board 1 with second fixing member 33 interposed therebetween. A current may or may not be passed through first circuit pattern 2d due to the operation of power conversion device 500. First circuit pattern 2d may be configured such that it is thermally coupled to and formed integrally with first circuit pattern 2a.

Second fixing member 33 is made of a material having a high thermal conductivity, such as a thermally conductive adhesive, an electrically conductive adhesive, or solder.

In power conversion device 500 according to the fifth embodiment, heat dissipating member 20 is electrically bonded at first fixing portion 20a to electrode portion 10b of switching element 10, and is also bonded at second fixing portion 22a to first circuit pattern 2d formed on first main surface 1a of printed board 1. Thus, the mechanical fixation of heat dissipating member 20 can be made more robust. As a result, power conversion device 500 according to the fifth embodiment can have improved vibration resistance.

When first circuit patterns 2a and 2d are thermally coupled together, the heat generated at semiconductor chip 10a can be dissipated through electrode portion 10b, first circuit pattern 2a, first circuit pattern 2d, second fixing member 33, heat dissipating member 20 and second insulating member 41 to second heat dissipator 51. Therefore, the number of heat dissipation paths through which to dissipate the heat generated at semiconductor chip 10a can be increased, thereby improving the heat dissipation of power conversion device 500 for the heat generated at semiconductor chip 10a.

Further, as shown in FIG. 13, heat dissipating member 20 may further include a second fixing portion 22b and a second fixing portion 22c in addition to second fixing portion 22a. Second fixing portion 22b and second fixing portion 22c are bonded to first main surface 1a of printed board 1 by a fixing member. In the configuration of heat dissipating member 20 shown in FIG. 13, heat dissipating member 20 can be bonded to first main surface 1a of printed board 1 by a plurality of fixing portions, so that the mechanical fixation of heat dissipating member 20 can be made more robust. When heat dissipating member 20 is made of metal, heat dissipating member 20 can serve as an electromagnetic shield, to prevent malfunction of electronic component 90 and the like disposed around switching element 10 caused by electromagnetic waves emitted to the surroundings due to the operation of switching element 10.

### Sixth Embodiment

The configuration of a power conversion device 600 according to a sixth embodiment of the present invention is described. Description of the configuration identical to or corresponding to those of the first, second, third, fourth and fifth embodiments is not repeated, and only a different portion of the configuration is described.

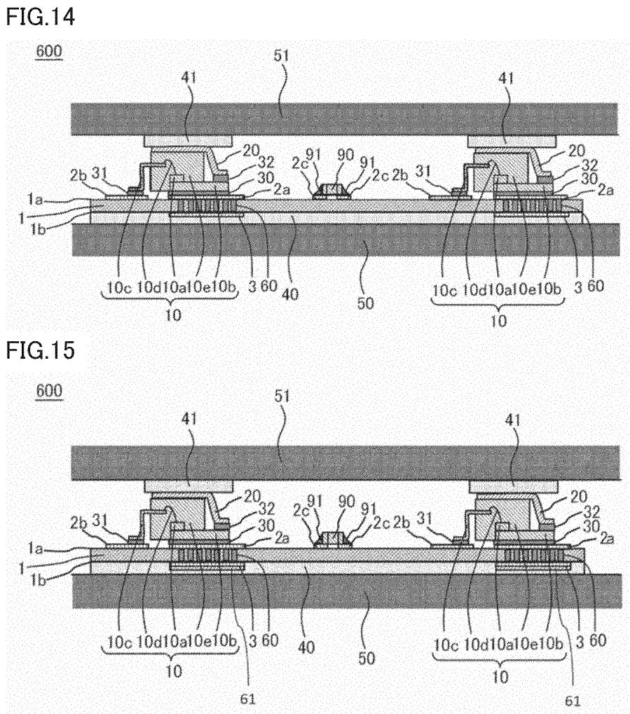

FIG. 14 is a cross-sectional view of power conversion device 600 according to the sixth embodiment. Power conversion device 600 according to the sixth embodiment includes a second circuit pattern 3 provided on second main surface 1b of printed board 1, and a plurality of vias 60 provided in printed board 1 each of which has one end in contact with first circuit pattern 2a and the other end in contact with second circuit pattern 3.

A current may or may not be passed through second circuit pattern 3 due to the operation of power conversion device 600.

Via 60 is a hole penetrating from first main surface 1a to second main surface 1b of printed board 1, has a cylindrical shape, and has a diameter of not less than 0.1 mm and not more than 3.0 mm. Via 60 has one end connected to first main surface 1a of printed board 1, and the other end connected to second main surface 1b of printed board 1. A conductive film may be formed on an inner wall surface of via 60. When a conductive film is formed on the inner wall surface of via 60, the conductive film has a thickness of not less than 0.01 mm and not more than 0.1 mm. Via 60 may be partially or completely filled with a thermally conductive adhesive, an electrically conductive adhesive, or solder.

At the portion where switching element 10 is disposed on printed board 1, thermal resistance between first main surface 1a and second main surface 1b can be reduced by via 60. For example, when printed board 1 is made of glass-reinforced epoxy, printed board 1 has a thermal conductivity of approximately 0.5 W/(m·K). When the conductive film formed on the inner wall surface of via 60 is made of copper and via 60 is filled with solder, on the other hand, copper has a thermal conductivity of approximately 370 W/(m·K) and solder has a thermal conductivity of approximately 50 W/(m·K), which are substantially higher than the thermal conductivity of printed board 1. Therefore, the heat dissipation can be improved in the third heat dissipation path through which the heat generated at semiconductor chip 10a is dissipated through electrode portion 10b, first circuit pattern 2a, vias 60, second circuit pattern 3 and first insulating member 40 to first heat dissipator 50.

FIG. 15 is a cross-sectional view showing a variation of power conversion device 600 according to the sixth embodiment. FIG. 15 shows a configuration in which a thermal diffusion plate 61 is provided on second circuit pattern 3 provided on second main surface 1b of printed board 1. Thermal diffusion plate 61 is bonded to second circuit pattern 3 by a fixing member (not shown). Because of the disposition of thermal diffusion plate 61 on second circuit pattern 3, the heat generated at semiconductor chip 10a can be diffused into a large area of thermal diffusion plate 61 in the third heat dissipation path through which the heat generated at semiconductor chip 10a is dissipated through electrode portion 10b, first circuit pattern 2a, vias 60, second circuit pattern 3, thermal diffusion plate 61 and first insulating member 40 to first heat dissipator 50, thereby reducing thermal resistance between second circuit pattern 3 and first insulating member 40. Therefore, power conversion device 600 can have improved heat dissipation.

Thermal diffusion plate 61 has a thermal conductivity of not less than 1.0 W/(m·K), preferably not less than 10.0 W/(m·K), and more preferably not less than 100.0 W/(m·K). Thermal diffusion plate 61 has a thickness of not less than 0.1 mm and not more than 100 mm. Thermal diffusion plate 61 is made of a metal material such as copper, a copper alloy, nickel, a nickel alloy, iron, an iron alloy, gold, or silver. Thermal diffusion plate 61 may employ, for example, a metal material in which a surface of one of aluminum, an aluminum alloy and a magnesium alloy is plated with one of a nickel plating film, a gold plating film, a tin plating film, and a copper plating film. Thermal diffusion plate 61 may employ, for example, a material in which a surface of resin having a high thermal conductivity is plated with one of a nickel plating film, a gold plating film, a tin plating film, and a copper plating film.

Power conversion device 600 according to the sixth embodiment includes second circuit pattern 3 provided on the second main surface of printed board 1, and the plurality of vias 60 in printed board 1 each of which has one end connected to first circuit pattern 2a and the other end connected to second circuit pattern 3. Thus, the heat dissipation can be improved in the third heat dissipation path through which the heat generated at semiconductor chip 10a is dissipated through electrode portion 10b, first circuit pattern 2a, vias 60, second circuit pattern 3 and first insulating member 40 to first heat dissipator 50.

### Seventh Embodiment

The configuration of a power conversion device 700 according to a seventh embodiment of the present invention is described. Description of the configuration identical to or corresponding to those of the first, second, third, fourth, fifth and sixth embodiments is not repeated, and only a different portion of the configuration is described.

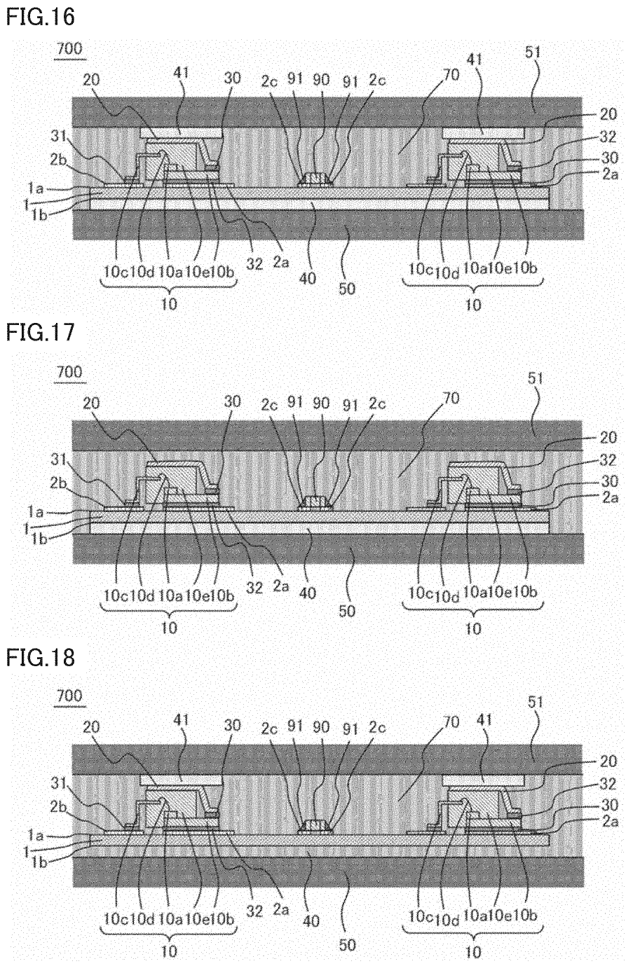

FIG. 16 is a cross-sectional view of power conversion device 700 according to the seventh embodiment. As shown in FIG. 16, power conversion device 700 is configured such that a sealing member 70 fills space between first heat dissipator 50 and second heat dissipator 51, to seal printed board 1, switching element 10, first fixing member 32 and heat dissipating member 20.

Sealing member 70 is a material having a thermal conductivity of not less than 0.1 W/(m·K), and preferably not less than 1.0 W/(m·K). Sealing member 70 is electrically insulative, and has a Young's modulus of not less than 1 MPa. Sealing member 70 is made of a resin material such as polyphenylene sulfide (PPS) or polyether ether ketone (PEEK) containing a thermally conductive filler. A rubber material such as silicon or urethane may be used as the material for sealing member 70.

Power conversion device 700 according to the seventh embodiment further includes paths through which the heat generated at semiconductor chip 10a is dissipated through sealing member 70 to first heat dissipator 50 and second heat dissipator 51. Therefore, power conversion device 700 can have improved heat dissipation for the heat generated at semiconductor chip 10a.

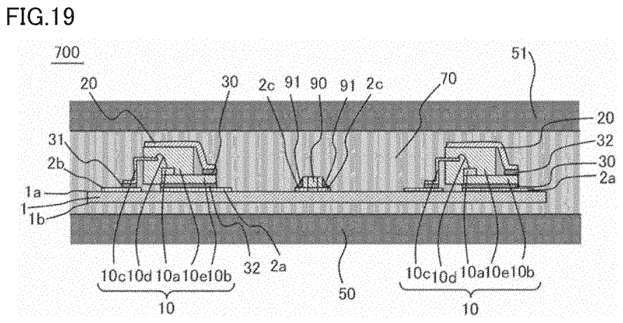

FIGS. 17, 18 and 19 are cross-sectional views showing variations of power conversion device 700 according to the seventh embodiment. FIG. 17 shows a configuration in which sealing member 70 fills space between heat dissipating portion 20b of heat dissipating member 20 and second heat dissipator 51. FIG. 18 shows a configuration in which sealing member 70 fills space between printed board 1 and first heat dissipator 50. FIG. 19 shows a configuration in which sealing member 70 fills both the space between heat dissipating portion 20b of heat dissipating member 20 and second heat dissipator 51, and the space between printed board 1 and first heat dissipator 50.

The configuration shown in FIG. 17 eliminates the need for second insulating member 41. The configuration shown in FIG. 18 eliminates the need for first insulating member 40. The configuration shown in FIG. 19 eliminates the need for first insulating member 40 and second insulating member 41.

A method of filling the space between first heat dissipator 50 and second heat dissipator 51 with sealing member 70 is described.

When spacer 52a is shaped as shown in FIG. 1, the filling with sealing member 70 is performed before first heat dissipator 50 and second heat dissipator 51 are fixed together by installation portion 52.

When spacer 52a is shaped as shown in FIG. 2 or 3, first heat dissipator 50 and second heat dissipator 51 are fixed together by installation portion 52 to manufacture the power conversion device, and then the manufactured power conversion device is disposed in a casing capable of accommodating the device, and the filling with sealing member 70 is performed. Alternatively, the power conversion device may be disposed in a casing filled with sealing member 70 in advance. When disposing the power conversion device in the casing and performing the filling with sealing member 70, a higher-performance power conversion device can be manufactured by disposing a plurality of power conversion devices, electronic components and the like in the casing.

When power conversion device 700 according to the seventh embodiment is configured as shown in FIG. 19, the filling with sealing member 70 is performed up to the position of second main surface 1b of printed board 1, and sealing member 70 is cured. Then, the filling with sealing member 70 is further performed above cured sealing member 70, each assembled member is disposed within sealing member 70, and then sealing member 70 is cured. Alternatively, it may be that the filling with sealing member 70 is performed up to the position of second main surface 1b of printed board 1, sealing member 70 is cured, each assembled member is disposed on cured sealing member 70, and then the filling with sealing member 70 is performed.

Since the space between first heat dissipator 50 and second heat dissipator 51 is filled with sealing member 70, power conversion device 700 according to the seventh embodiment further includes a path through which the heat generated at semiconductor chip 10a is dissipated through sealing member 70 to first heat dissipator 50 or second heat dissipator 51. Therefore, power conversion device 700 can have improved heat dissipation for the heat generated at semiconductor chip 10a. In addition, since sealing member 70 can be used as first insulating member 40 and second insulating member 41, the cost of components forming power conversion device 700 can be reduced. Further, since the space between first heat dissipator 50 and second heat dissipator 51 can be filled with sealing member 70, the mechanical fixation of the components can be made more robust, so that power conversion device 700 can have improved vibration resistance.

While the heat dissipating member has been described as having a thickness of from 0.1 mm to 3 mm and being in the form of a plate having a high thermal conductivity in each embodiment above, the shape of the heat dissipating member is not limited to a plate, and the thickness of the heat dissipating member is not limited to from 0.1 mm to 3 mm. The heat dissipating member can have any shape and dimension insofar as it includes the features described in the claims.

The present invention is not limited to the shapes described in the first to seventh embodiments, and the embodiments can be combined in any manner, or can be modified or omitted as appropriate, within the scope of the invention.

Although the embodiments of the present invention have been described, it should be understood that the embodiments disclosed herein are illustrative and non-restrictive in every respect. The scope of the present invention is defined by the terms of the claims, and is intended to include any modifications within the meaning and scope equivalent to the terms of the claims.

### REFERENCE SIGNS LIST

100, 200, 300, 400, 500, 600, 700 power conversion device;
1 printed board; 1a first main surface; 1b second main surface;
2a, 2b, 2c, 2d first circuit pattern; 3 second circuit pattern; 4 harness;
10 switching element; 10a semiconductor chip; 10b electrode portion; 10c lead terminal; 10d wire; 10e resin portion; 10f heat dissipation surface; 10g sealed surface; 11a through hole;
20 heat dissipating member; 20a first fixing portion; 20b heat dissipating portion; 20c spring portion; 21a protrusion; 22a, 22b, 22c second fixing portion;
30 first bonding member; 31 second bonding member; 32 first fixing member; 33 second fixing member; 40 first insulating member; 41 second insulating member;
50 first heat dissipator; 51 second heat dissipator; 52 installation portion;
52a spacer; 52b fastening member;
60 via; 61 thermal diffusion plate;
70 sealing member;
90 electronic component; 91 third bonding member.

1-14. (canceled)

15. A power conversion device comprising:
a first heat dissipator;
a second heat dissipator opposed to the first heat dissipator;
a printed board having a front surface on which a first circuit pattern is formed, and a rear surface opposed to the first heat dissipator;
a first insulating member provided between the first heat dissipator and the printed board;
a switching element including
an electrode portion having a rear surface electrically bonded to the first circuit pattern with a first bonding member interposed therebetween, the electrode portion being formed of a metal plate,
a semiconductor chip electrically bonded to the electrode portion, and
a resin portion sealing a part of a side of a front surface of the electrode portion and the semiconductor chip;
a first fixing member having a rear surface bonded to an exposed surface on the side of the front surface of the electrode portion;
a heat dissipating member having one end bonded to the front surface of the electrode portion with the first fixing member interposed therebetween, the one end being a first fixing portion, and the other end provided between a surface of the resin portion of the switching element opposed to the second heat dissipator and the second heat dissipator, the other end being a heat dissipating portion;
a second insulating member sandwiched between the second heat dissipator and the heat dissipating member; and
an installation portion that has one end coupled to the first heat dissipator and the other end coupled to the second heat dissipator, and that fixes the first heat dissipator and the second heat dissipator together,
the heat dissipating member further comprising a second fixing portion bonded to the first circuit pattern with a second fixing member interposed therebetween.

16. The power conversion device according to claim 15, further comprising a sealing member filling space between the first heat dissipator and the second heat dissipator to seal the first insulating member, the printed board, the switching element, the first fixing member, the heat dissipating member and the second insulating member.

17. The power conversion device according to claim 15, wherein
the heat dissipating portion is a flat plate, and
the first fixing portion, the second fixing portion and the heat dissipating portion are connected together by an inclined portion, the inclined portion being a flat plate inclined relative to the first fixing portion and the second fixing portion, and the first fixing portion, the second fixing portion, the heat dissipating portion and the inclined portion are integrally formed.

18. The power conversion device according to claim 15, further comprising a harness that is electrically bonded to the first circuit pattern, and that supplies electric power to the switching element from outside.

19. The power conversion device according to claim 15, wherein
a thermally conductive member is provided between the surface of the resin portion of the switching element opposed to the second heat dissipator and the heat dissipating member.

20. The power conversion device according to claim 15, wherein
the electrode portion has a through hole,
the one end of the heat dissipating member has a protrusion, and
the protrusion is fitted in the through hole.

21. The power conversion device according to claim 15, wherein
the printed board comprises
a second circuit pattern provided on the rear surface, and
a via provided in the printed board and having one end connected to the first circuit pattern and the other end connected to the second circuit pattern.

22. The power conversion device according to claim 21, wherein
a thermal diffusion plate is bonded on the second circuit pattern.

23. A power conversion device comprising:
a first heat dissipator;
a second heat dissipator opposed to the first heat dissipator;
a printed board having a front surface on which a first circuit pattern is formed, and a rear surface opposed to the first heat dissipator;
a switching element including
an electrode portion having a rear surface electrically bonded to the first circuit pattern with a first bonding member interposed therebetween, the electrode portion being formed of a metal plate,
a semiconductor chip electrically bonded to the electrode portion, and
a resin portion sealing a part of a side of a front surface of the electrode portion and the semiconductor chip;
a first fixing member having a rear surface bonded to an exposed surface on the side of the front surface of the electrode portion;
a heat dissipating member having one end bonded to the front surface of the electrode portion with the first fixing member interposed therebetween, the one end being a first fixing portion, and the other end provided between a surface of the resin portion of the switching element opposed to the second heat dissipator and the second heat dissipator, the other end being a heat dissipating portion;
a sealing member filling space between the first heat dissipator and the second heat dissipator to seal the printed board, the switching element, the first fixing member and the heat dissipating member; and
an installation portion that has one end coupled to the first heat dissipator and the other end coupled to the second heat dissipator, and that fixes the first heat dissipator and the second heat dissipator together,
the heat dissipating member further comprising a second fixing portion bonded to the first circuit pattern with a second fixing member interposed therebetween.

24. The power conversion device according to claim 23, wherein
a first insulating member is provided between the first heat dissipator and the printed board.

25. The power conversion device according to claim 23, wherein
a second insulating member is provided between the second heat dissipator and the heat dissipating member.

26. The power conversion device according to claim 23, further comprising a harness that is electrically bonded to the first circuit pattern, and that supplies electric power to the switching element from outside.

27. The power conversion device according to claim 23, wherein
a thermally conductive member is provided between the surface of the resin portion of the switching element opposed to the second heat dissipator and the heat dissipating member.

28. The power conversion device according to claim 23, wherein
the electrode portion has a through hole,
the one end of the heat dissipating member has a protrusion, and
the protrusion is fitted in the through hole.

29. The power conversion device according to claim 23, wherein
the printed board comprises
a second circuit pattern provided on the rear surface, and
a via provided in the printed board and having one end connected to the first circuit pattern and the other end connected to the second circuit pattern.

30. The power conversion device according to claim 29, wherein
a thermal diffusion plate is bonded on the second circuit pattern.

31. A power conversion device comprising:
a first heat dissipator;
a second heat dissipator opposed to the first heat dissipator;
a printed board having a front surface on which a first circuit pattern is formed, and a rear surface opposed to the first heat dissipator;
a first insulating member provided between the first heat dissipator and the printed board;
a switching element including
an electrode portion having a rear surface electrically bonded to the first circuit pattern with a first bonding member interposed therebetween,
a semiconductor chip electrically bonded to a front surface of the electrode portion,
a lead terminal having one end electrically bonded to the first circuit pattern with a second bonding member interposed therebetween,
a resin portion sealing a part of a side of the front surface of the electrode portion, the other end of the lead terminal and the semiconductor chip, and
a wire to electrically connect the other end of the lead terminal to the semiconductor chip;
a first fixing member having a rear surface bonded to an exposed surface on the side of the front surface of the electrode portion;
a heat dissipating member having one end bonded to the front surface of the electrode portion with the first fixing member interposed therebetween, the one end being a first fixing portion, and the other end provided between a surface of the resin portion of the switching element opposed to the second heat dissipator and the second heat dissipator, the other end being a heat dissipating portion;
a second insulating member sandwiched between the second heat dissipator and the switching element; and
an installation portion that has one end coupled to the first heat dissipator and the other end coupled to the second heat dissipator, and that fixes the first heat dissipator and the second heat dissipator together,
the heat dissipating portion being a flat plate,
the bonding portion and the heat dissipating portion being connected together by an inclined portion, the inclined portion being a flat plate inclined relative to the bonding portion, and the bonding portion, the heat dissipating portion and the inclined portion being integrally formed, and
the heat dissipating member further comprising a second fixing portion bonded to the first circuit pattern with a second fixing member interposed therebetween.
